(19) United States
(12) Patent Application Publication
(10) Pub. No.: US 2014/0030826 A1
(43) Pub. Date: Jan. 30, 2014

(54) POLISHING METHOD

(71) Applicants: Shinrou Ohta, Tokyo (JP); Toshikazu Nomura, Tokyo (JP); Takeshi Iizumi, Tokyo (JP)

(72) Inventors: Shinrou Ohta, Tokyo (JP); Toshikazu Nomura, Tokyo (JP); Takeshi Iizumi, Tokyo (JP)

(21) Appl. No.: 13/556,568

(22) Filed: Jul. 24, 2012

(51) Int. Cl. H01L 21/66

(52) U.S. Cl. 438/10; 257/E21.528

(57) ABSTRACT

A method of polishing a wafer having a Ru film and a Ta film or TaN film beneath the Ru film is provided. This polishing method includes: polishing the Ru film by bringing the wafer into sliding contact with a polishing pad; measuring a thickness of the Ru film by a film thickness sensor while polishing the Ru film; calculating a derivative value of an output value of the film thickness sensor; detecting a predetermined point of change in the derivative value; and determining a removal point of the Ru film from a point of time when the point of change is detected.

### BACKGROUND OF THE INVENTION

1. Field of the Invention

The present invention relates to a polishing method for a wafer, and more particularly to a method of polishing a wafer having multilayered conductive layers formed thereon.

2. Description of the Related Art

In interconnect fabrication process of a wafer, a metal film as material of interconnects is formed and then chemical mechanical polishing (CMP) is performed so as to remove unwanted part of the metal film that is not used for the interconnects. In this polishing process, a conductive layer, which is a barrier layer located beneath the metal film, is removed by polishing after the unwanted metal film is removed. Further, a hard mask film, which is formed beneath the conductive layer, is also removed by polishing. The polishing process is stopped when the metal interconnects reach a predetermined height. This predetermined height is a height necessary for the metal interconnects to have a predetermined value of resistance.

The hard mask film, which is a dielectric film made from insulating material or a metal film, is formed so as to cover interlevel dielectric. The interlevel dielectric is made from a fragile Low-k material or the like. The hard mask film is provided for the purpose of protecting the interlevel dielectric from physical processing or the like, such as CMP or dry etching for forming interconnect trenches.

FIG. 1 is a cross-sectional view showing an example of the multilayer structure forming the interconnects. As shown in FIG. 1, a hard mask film 103, which is made from, for example, SiO₂, is formed on an interlevel dielectric 102 which is made from SiO₂ or Low-k material. Via holes 104 and trenches 105 are formed in the interlevel dielectric 102. A conductive layer 106 is formed on surfaces of the hard mask film 103, the via holes 104, and the trenches 105. The conductive layer 106 comprises a Ru film (ruthenium film) 106a and a Ta film (tantalum film) or TaN film (tantalum nitride film) 106b formed beneath the Ru film 106a. Hereinafter, the Ta film or TaN film will be referred to as a Ta/TaN film.

After the conductive layer 106 is formed, copper plating is performed on the wafer to fill the via holes 104 and the trenches 105 with copper and to deposit a copper film 107, which is a metal film, on the conductive layer 106. Thereafter, chemical mechanical polishing (CMP) is conducted so as to remove unwanted parts of the copper film 107, the conductive layer 106, and the hard mask film 103, so that copper remains only in the via holes 104 and the trenches 105. This copper forms the interconnects of a semiconductor device. As shown by a dotted line in FIG. 1, polishing is terminated when the interconnects have a predetermined height.

The conductive layer 106 serves as a barrier layer against the copper film 107. Since the Ru film 106a, constituting a part of the conductive layer 106, can be made thin, the Ru film 106a can contribute to the formation of thinner barrier layer. Moreover, since the Ru film 106a has a lower value of resistance than that of the Ta and TaN that are conventionally used for the barrier layer, use of the Ru film 106a is expected to contribute to realization of finer semiconductor device. However, the Ru film 106a does not have a function to prevent copper diffusion. Thus, the Ta/TaN film 106b that can prevent copper diffusion is formed beneath the Ru film 106a.

The purpose of removing the unwanted part of conductive layer 106 by CMP is to prevent short circuit between the interconnects. This is the same as the purpose of removing the unwanted part of the copper film 107. However, a polishing rate of the Ru film 106a is lower than a polishing rate of the Ta/TaN film 106b. Due to this fact, the unwanted Ru film 106a cannot be removed if a variation in thickness exists in the Ru film 106a. As a result, the short circuit between the interconnects could occur.

### SUMMARY OF THE INVENTION

The present invention has been made for solving the above drawback. It is therefore an object of the present invention to provide a polishing method and a polishing apparatus capable of reliably detecting a removal point of the Ru film formed on the Ta film or TaN film.

One aspect of the present invention for achieving the above object is to provide a method of polishing a wafer having a Ru film and a Ta film or TaN film beneath the Ru film. The method includes: polishing the Ru film by bringing the wafer into sliding contact with a polishing pad; measuring a thickness of the Ru film by a film thickness sensor while polishing the Ru film; calculating a derivative value of an output value of the film thickness sensor; detecting a predetermined point of change in the derivative value; and determining a removal point of the Ru film from a point of time when the predetermined point of change is detected.

In a preferred aspect of the present invention, the predetermined point of change is a local maximum point or a local minimum point of the derivative value.

In a preferred aspect of the present invention, the removal point of the Ru film is a point of time when a predetermined period of time has elapsed from the point of time when the predetermined point of change is detected.

In a preferred aspect of the present invention, the predetermined period of time includes zero.

In a preferred aspect of the present invention, the polishing pad has a fine porous structure uniformly formed in the polishing pad in its entirety and has open cells formed in the fine porous structure.

In a preferred aspect of the present invention, the method further includes: after determining the removal point of the Ru film, increasing polishing pressure applied from the wafer to the polishing pad; and polishing the Ta film or TaN film by bringing the wafer into sliding contact with the polishing pad at the increased polishing pressure.

In a preferred aspect of the present invention, the method further includes: after determining the removal point of the Ru film, lowering polishing pressure applied from the wafer to the polishing pad; and polishing the Ta film or TaN film by bringing the wafer into sliding contact with the polishing pad at the lowered polishing pressure.

In a preferred aspect of the present invention, the polishing of the Ru film comprises polishing the Ru film by bringing the wafer into sliding contact with the polishing pad while supplying the polishing pad with a first polishing liquid; and the method further includes, after determining the removal point of the Ru film, polishing the Ta film or TaN film by bringing the wafer into sliding contact with the polishing pad while supplying the polishing pad with a second polishing liquid, instead of the first polishing liquid.

In a preferred aspect of the present invention, the method further includes: before polishing the Ru film, polishing a copper film formed on the Ru film.

In a preferred aspect of the present invention, the Ru film and the Ta film or TaN film form a barrier layer for preventing copper diffusion.

In a preferred aspect of the present invention, the film thickness sensor is an eddy current sensor.

The polishing rate (i.e., a thickness of film removed per unit time, also referred to as removal rate) of the Ru film differs greatly from the polishing rate of the Ta film or TaN film. Therefore, when the Ru film is removed, a distinctive point of change appears in the derivative value of the output value of the eddy current sensor. Therefore, the removal point of the Ru film can be detected accurately based on this point of change.

### BRIEF DESCRIPTION OF THE DRAWINGS

FIG. 1 is a cross-sectional view showing an example of a multilayer structure forming interconnects;

FIG. 2 is a polishing apparatus for performing a polishing method according to an embodiment of the present invention;

FIG. 3 is a graph representing output value of an eddy current sensor when polishing a conductive layer that serves as a barrier layer made of a Ru film and a TaN film;

FIG. 4 is a graph representing derivative value of the output value of the eddy current sensor shown in FIG. 3;

FIG. 5 is a graph showing a change in the output value of the eddy current sensor when polishing the conductive layer (barrier layer) made from only a Ta/TaN film;

FIG. 6 is a schematic view of a cross section of a polishing pad;

FIG. 7 is a graph showing wafer polishing result when using the polishing pad having fine porous structure uniformly formed in its entirety and having open cells formed in the fine porous structure, and wafer polishing result when using a conventional polishing pad having fine porous structure that is locally formed and having open cells formed therein;

FIG. 8 is a wafer processing apparatus capable of polishing, cleaning, and drying a wafer;

FIG. 9 is an example of wafer processing flow;

FIG. 10 is another example of wafer processing flow; and

FIG. 11 is still another example of wafer processing flow.

### DETAILED DESCRIPTION OF THE PREFERRED EMBODIMENTS

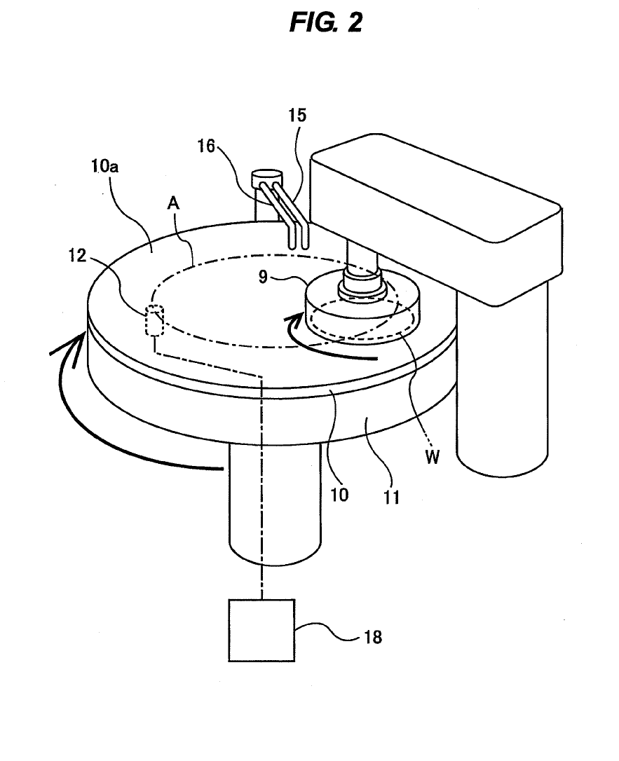

FIG. 2 is a polishing apparatus for performing a polishing method according to an embodiment of the present invention. The polishing apparatus includes: a polishing table 11 supporting a polishing pad 10; a top ring 9 for holding and rotating a wafer W; a slurry supply mechanism 15 for supplying a polishing liquid (i.e., slurry) onto the polishing pad 10; a water supply mechanism 16 for supplying pure water (DIW) onto the polishing pad 10; and an eddy current sensor 12 for measuring film thickness of the wafer W. The eddy current sensor 12 is located in the polishing table 11. Each time the polishing table 11 makes one revolution, the eddy current sensor 12 obtains film thickness data that varies in accordance with the film thickness of the wafer W.

The top ring 9 and the polishing table 11 rotate in the same direction as indicated by arrows. In this state, the top ring 9 presses the wafer W against a polishing surface 10a of the polishing pad 10. The slurry supply mechanism 15 supplies the polishing liquid onto the polishing pad 10, so that the wafer W is polished by the sliding contact with the polishing pad 10 in the presence of the polishing liquid. During polishing of the wafer W, the eddy current sensor 12 rotates together with the polishing table 11 and obtains the film thickness data while sweeping a surface of the wafer W as indicated by symbol A. The eddy current sensor 12 is coupled to a polishing controller 18. This polishing controller 18 is configured to monitor progress of polishing of the wafer W based on the film thickness data obtained by the eddy current sensor 12.

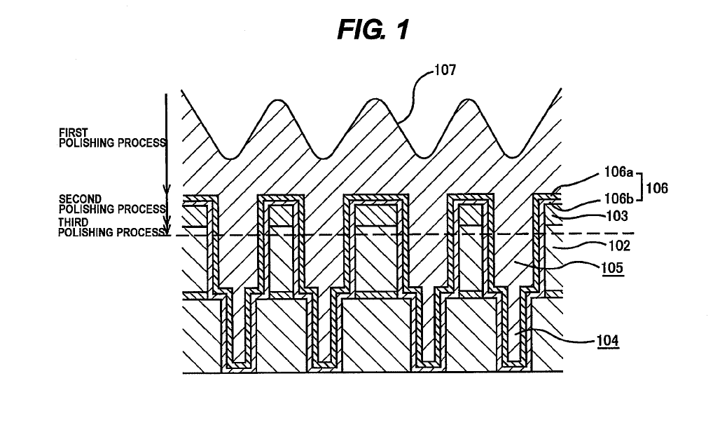

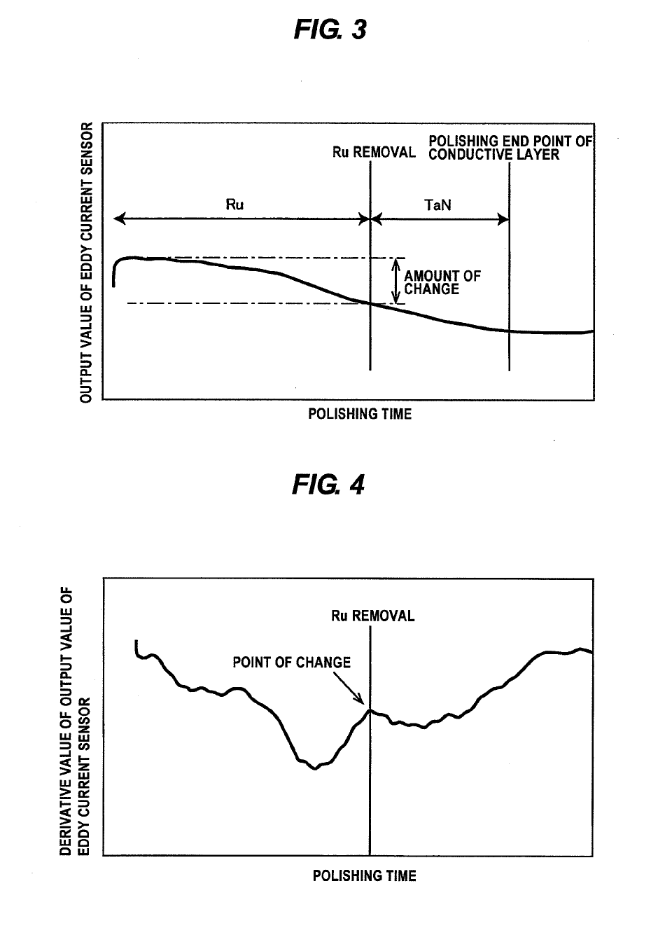

The wafer W to be polished is a wafer having a multilayer structure shown in FIG. 1. FIG. 3 is a graph showing output value of the eddy current sensor when polishing conductive layer 106 serving as a barrier layer constituted by Ru film (represented by reference numeral 106a in FIG. 1) and TaN film (represented by reference numeral 106b in FIG. 1). In FIG. 3, vertical axis represents the output value of the eddy current sensor 12, i.e., film thickness, and horizontal axis represents polishing time. As shown in FIG. 3, the output value of the eddy current sensor 12 varies with the polishing time.

FIG. 4 is a graph showing derivative value of the output value of the eddy current sensor 12 shown in FIG. 3. The derivative value of the output value of the eddy current sensor 12 represents a slope of the graph shown in FIG. 3. In other words, the derivative value of the output value of the eddy current sensor 12 represents amount of change in the output value of the eddy current sensor 12 per unit time. As shown in FIG. 3, the output value of the eddy current sensor 12 when the Ru film is being polished varies in a manner different from a manner of change in the output value of the eddy current sensor 12 when the TaN film is being polished. This is due to a difference in the polishing rate between the Ru film and the TaN film. As a result of such a difference in the polishing rate, a distinctive point of change in the derivative value of the output value of the eddy current sensor 12, i.e., a local maximum point (or local minimum point), appears when the Ru film is removed, as shown in FIG. 4. The local maximum point and the local minimum point of the derivative value are points where a local maximum value and a local minimum value of the derivative value appear. Although not shown in the drawings, a similar distinctive point appears in the case of the Ta film.

The polishing controller 18 is configured to detect removal of the Ru film based on this point of change in the output value of the eddy current sensor 12. When the point of change appears, a part of Ru film may still remain. Therefore, the polishing controller 18 determines the removal point of the Ru film by determining whether or not a predetermined period of time has elapsed from a point of time when the point of change in the output value of the eddy current sensor 12 appears. This predetermined period of time may be zero.

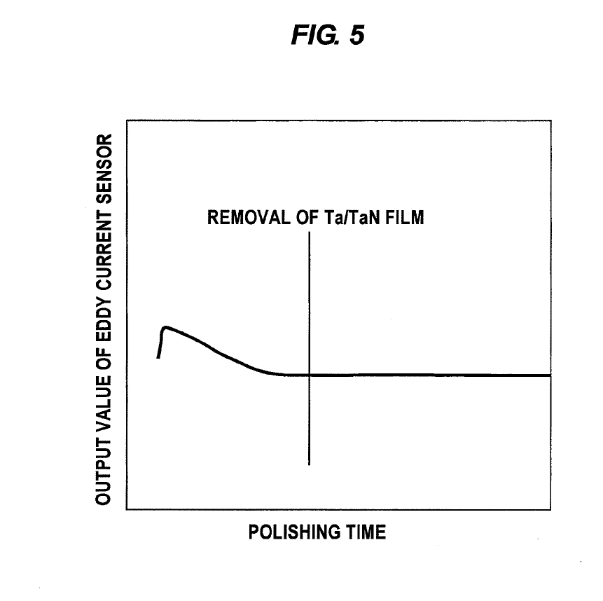

FIG. 5 is a graph showing the change in the output value of the eddy current sensor 12 when polishing the conductive layer as the barrier layer made from only the Ta film or TaN film (which will be hereinafter referred to as Ta/TaN film). As can be seen from FIG. 5, during polishing of the Ta/TaN film, the output value of the eddy current sensor 12 varies gently. Accordingly, although not shown in the drawing, a distinctive point of change does not appear in the derivative value of the output value.

When polishing the wafer having the multilayer structure including the Ru film and the underlying Ta/TaN film, the difference in the polishing rate between the Ru film and the Ta/TaN film results in appearance of the distinctive point of change in the derivative value of the output value of the eddy current sensor 12. Therefore, the polishing controller 18 can determine the removal point of the Ru film accurately from the distinctive point of change. Determining of the removal point is a process of judging whether or not the film is removed.

It is possible to adjust the polishing process of the wafer W based on the detection of the removal point of the Ru film. Specifically, it is possible to change polishing conditions of the wafer W after the removal of the Ru film is detected. For example, polishing pressure applied from the wafer W to the polishing pad 10 may be reduced after the removal of the Ru film is detected. This operation can reduce scratches on a polished surface of the wafer W. In another example, in order to shorten the polishing time, the polishing pressure applied from the wafer W to the polishing pad 10 may be increased after the removal of the Ru film is detected.

As shown in FIG. 3, the output value of the eddy current sensor 12 decreases in accordance with a decrease in the film thickness. That is, there is a correlation between amount of change in the output value of the eddy current sensor 12 and amount of film removed. Therefore, it is also possible to detect the removal point of the Ru film from the amount of change in the output value of the eddy current sensor 12. In this example, the correlation between the amount of the Ru film removed and the amount of change in the output value of the eddy current sensor 12 is obtained in advance by: polishing a plurality of wafers having the same structure; and measuring initial film thickness and film thickness after polishing.

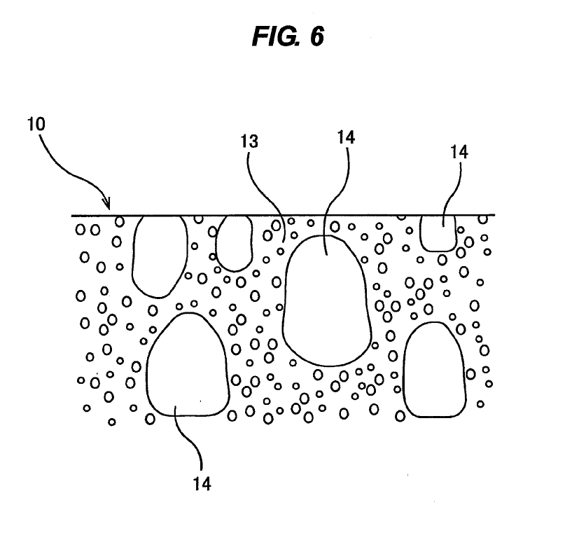

The scratches on the polished surface of the wafer W can be a cause of defect that lowers the reliability of devices. In order to improve such defect, as shown in FIG. 6, the polishing pad 10 has a fine porous structure 13 uniformly formed in the polishing pad 10 in its entirety and have open cells 14 formed in the fine porous structure 13. Since the fine porous structure 13 is formed uniformly in the polishing pad 10 in its entirety, stress concentration is unlikely to occur on the polishing surface of the polishing pad 10. Therefore, the polishing pad 10 absorbs impact and the scratches are less likely to be formed on the wafer W.

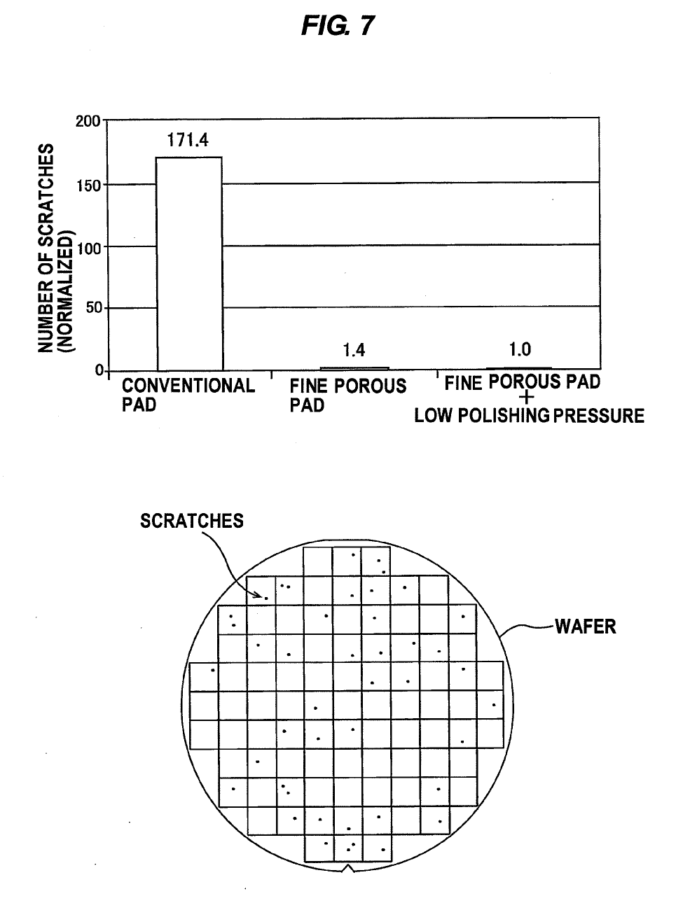

FIG. 7 is a graph showing wafer polishing result when using the above-described polishing pad 10 and wafer polishing result when using a conventional polishing pad having fine porous structure that is locally formed and having open cells formed therein. In FIG. 7, vertical axis represents normalized value of the number of scratches formed on the wafer. The normalized number of scratches is obtained by dividing the total number of scratches on the wafer by the smallest total number of scratches that is obtained under the condition that the wafer is pressed against the polishing pad 10 with low polishing pressure. As shown in FIG. 7, the number of scratches in the case of using the conventional polishing pad is 171.4, while the number of scratches in the case of using the polishing pad 10 is 1.4. As can be seen from this graph, use of the polishing pad 10 having the fine porous structure uniformly formed in the polishing pad 10 in its entirety and having open cells formed in the fine porous structure can reduce the number of scratches remarkably.

Instead of the eddy current sensor 12, an optical film-thickness monitoring sensor may be used as the film thickness sensor. The optical film-thickness monitoring sensor is a sensor configured to direct light to the wafer and monitor the film thickness based on spectrum of reflected light from the wafer. The spectrum of the reflected light varies in accordance with the film thickness. This is because a manner of interference of light wave reflected from a surface of a film and light wave reflected from interface between the film and an underlying layer varies in accordance with the film thickness. When a metal film becomes extremely thin, the light can pass through the metal film. Therefore, the optical film-thickness monitoring sensor can measure the thickness of the very thin metal film.

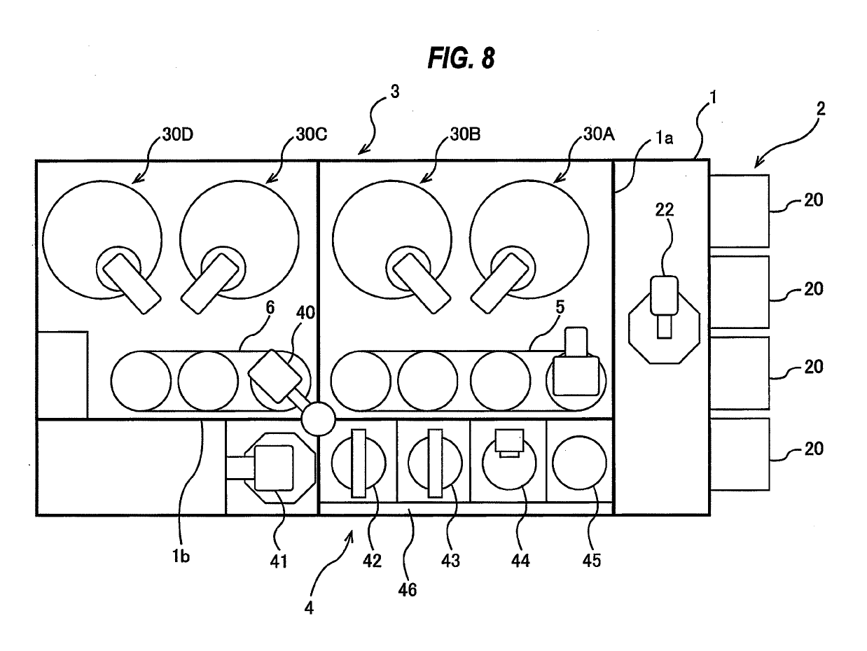

Next, a wafer processing apparatus capable of conducting the polishing method according to the present invention will be described. FIG. 8 is the wafer processing apparatus capable of polishing, cleaning, and drying a wafer. As shown in FIG. 8, the wafer processing apparatus has a housing 1 in a rectangular shape. An interior space of the housing 1 is partitioned into a loading-unloading section 2, a polishing section 3, and a cleaning section 4 by partitions 1a and 1b.

The loading-unloading section 2 has front loaders 20 on which wafer cassettes are mounted. The loading-unloading section 2 has a first transfer robot 22 which is movable along an arrangement direction of the front loaders 20. This first transfer robot 22 is able to access the wafer cassettes mounted on the front loaders 20. The first transfer robot 22 has vertically arranged two hands, which are separately used. For example, the upper hand can be used for returning a polished wafer to the wafer cassette, and the lower hand can be used for transporting a non-polished wafer.

The polishing section 3 includes a first polishing unit 30A, a second polishing unit 30B, a third polishing unit 30C, and a fourth polishing unit 30D. Each of these polishing units 30A, 30B, 30C, and 30D has the same structure as the polishing apparatus shown in FIG. 2, and will not be described in detail. In the polishing section 3, a first linear transporter 5 is disposed so as to transport the wafer between the first polishing unit 30A and the second polishing unit 30B. Similarly, a second linear transporter 6 is disposed so as to transport the wafer between the third polishing unit 30C and the fourth polishing unit 30D.

A swing transporter 40 for transporting a polished wafer to the cleaning section 4 is provided between the polishing section 3 and the cleaning section 4. The cleaning section 4 includes a reversing machine 41 for reversing the wafer received from the swing transporter 40, three cleaning machines 42, 43, and 44 for cleaning the polished wafer, a drying machine 45 for drying the cleaned wafer, and a transporting unit 46 for transporting the wafer between the reversing machine 41, the cleaning machines 42-44, and the drying machine 45.

The transporting unit 46 has a plurality of arms (not shown) configured to grasp wafers. These arms are configured to transport the wafers horizontally and simultaneously between the reversing machine 41, the cleaning machines 42-44, and the drying machine 45. The cleaning machine 42 and the cleaning machine 43 may be, for example, a roll type cleaning machine which rotates upper and lower roll-shaped sponges and presses them against front and rear surfaces of the wafer to clean the front and rear surfaces of the wafer. The cleaning machine 44 may be, for example, a pencil type cleaning machine which rotates a hemispherical sponge and presses it against the wafer to clean the wafer.

The drying machine 45 may be, for example, a IPA drying machine, which is configured to blow gas containing vapor of isopropyl alcohol onto a surface of the wafer to dry the wafer. The wafer, that has been dried by the drying machine 45, is returned to the wafer cassette on the front loader 20 by the first transfer robot 22.

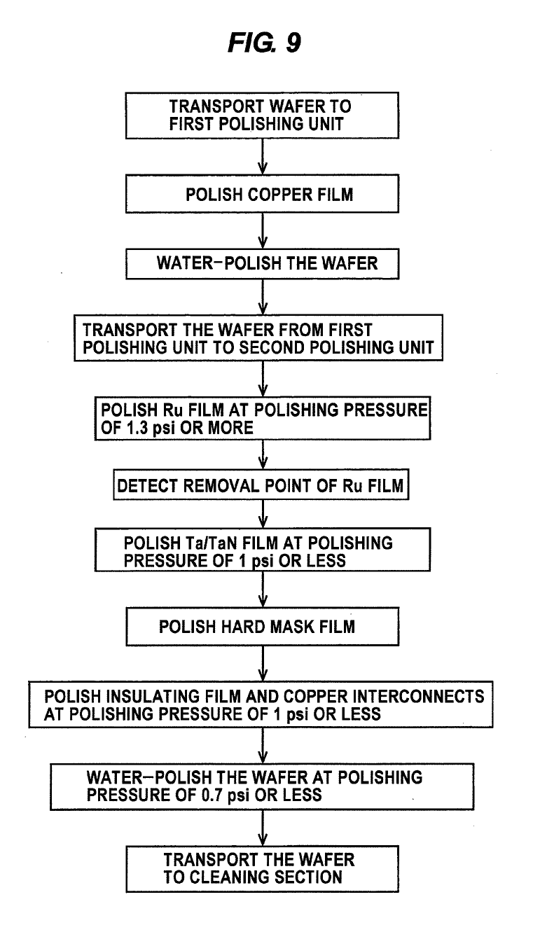

Next, examples of wafer processing flow will be described with reference to FIG. 1, FIG. 8, and FIG. 9. The wafer is transported to the first polishing unit 30A, where the copper film 107 is polished (a first polishing process). After unwanted copper film 107 is removed, the wafer is water-polished while the water supply mechanism 16 (see FIG. 2) is supplying pure water (DIW) onto the polishing pad 10. A polishing load on the wafer during water polishing may be set to zero. After the water polishing process, the wafer is transported from the first polishing unit 30A to the second polishing unit 30B by the first linear transporter 5.

In the second polishing unit 30B, the conductive layer 106, which serves as the barrier layer, is firstly polished. This polishing process of the conductive layer 106 is divided into polishing of the Ru film 106a which is an upper conductive layer (a first stage of the second polishing process) and polishing of the Ta/TaN film 106b which is a lower conductive layer (a second stage of the second polishing process). The removal point of the Ru film 106a is detected based on the output value of the eddy current sensor 12 according to the above-described method. When the removal point of the Ru film 106a is detected, the polishing pressure is switched from a first polishing pressure to a second polishing pressure. Specifically, polishing of the Ru film 106a is performed at the first polishing pressure of 1.3 psi [9.0 kPa] or more, and polishing of the Ta/TaN film is performed at the second polishing pressure of 1.0 psi [6.9 kPa] or less. After the conductive layer 106 is removed, the hard mask film 103 is subsequently polished (a third stage of the second polishing process). This polishing is performed until the hard mask film 103 is removed.

Subsequently, the interlevel dielectric 102 and the copper interconnects remaining in the trenches 105 are polished (a third polishing process). This polishing is performed at polishing pressure of 1.0 psi or less and is terminated when the copper interconnects reach a predetermined height. Then, the wafer is water-polished at polishing pressure of 0.7 psi [4.8 kPa] or less. The purpose of the water polishing process is to remove the polishing liquid (slurry) and polishing debris remaining on the wafer and the polishing pad 10.

The polished wafer is transported to the cleaning section 4 by the swing transporter 40. The wafer is cleaned and dried in the cleaning section 4. The dried wafer is returned to the wafer cassette on the front loader 20 by the first transfer robot 22.

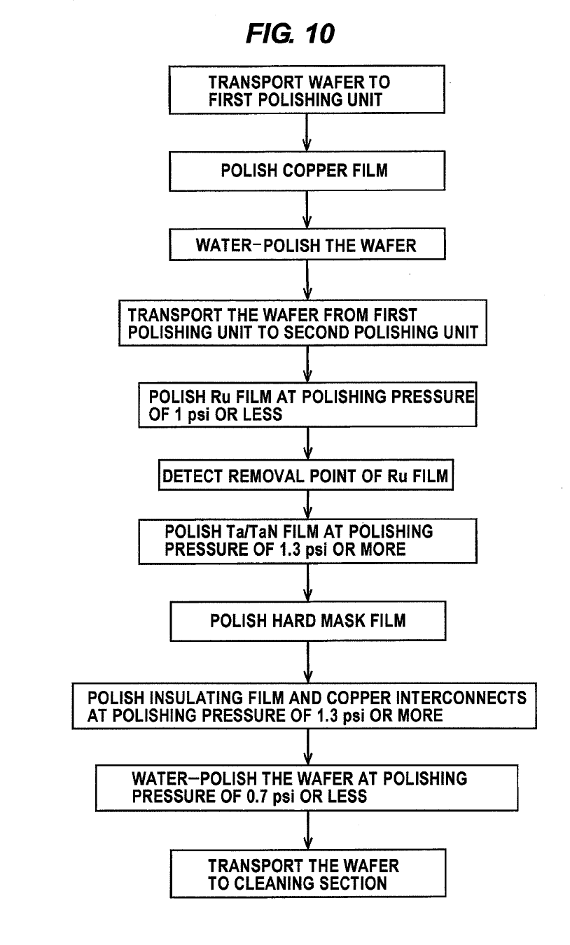

FIG. 10 is a flow chart of another example of the wafer processing flow. In this processing flow, the polishing pressures in the second polishing process and the third polishing process differ from those in the process flow shown in FIG. 9. Specifically, polishing of the Ru film 106a is performed at the first polishing pressure of 1.0 psi or less, and the Ta/TaN film is performed at the second polishing pressure of 1.3 psi or more. Further, polishing of the interlevel dielectric 102 and the copper interconnects remaining in the trenches 105 (the third polishing process) is performed at polishing pressure of 1.3 psi or more. Other steps are the same as those in FIG. 9.

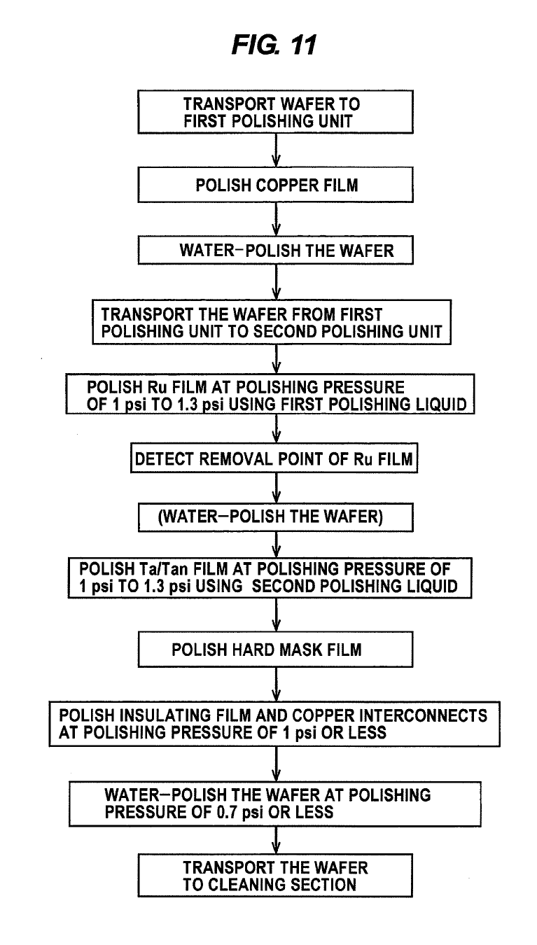

FIG. 11 is a flow chart showing still another example of the wafer processing flow. In this example, two types of polishing liquids, i.e., a first polishing liquid and a second polishing liquid, are used. Specifically, the Ru film 106a is polished with use of the first polishing liquid for ruthenium capable of increasing the polishing rate of the Ru film 106a. When the removal of the Ru film 106a is detected based on the output value of the eddy current sensor 12 according to the above-described method, the polishing liquid to be supplied onto the polishing pad 10 is switched from the first polishing liquid for ruthenium to the second polishing liquid for Ta or TaN. The first polishing liquid has a property of increasing the polishing rate of the Ru film 106a, and the second polishing liquid has a property of further increasing the polishing rate of the Ta/TaN film 106b.

Polishing of the Ru film 106a and polishing of the Ta/TaN 106b are performed at polishing pressure in a range of 1 psi to 1.3 psi. The polishing pressure on the Ru film 106a may differ from the polishing pressure on the Ta/TaN film 106b. Further, in order to remove the first polishing liquid for ruthenium and the polishing debris, water-polishing may be performed between polishing of the Ru film 106a and polishing of Ta/TaN film 106b.

While the above-discussed embodiments show examples of polishing the multilayer structure including combination of the Ru film and Ta/TaN film, the present invention can also be applied to polishing of multilayer structure including combination of a metal film and a conductive film with greatly different polishing rates.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims and equivalents.

What is claimed is:

1. A method of polishing a wafer having a Ru film and a Ta film or TaN film beneath the Ru film, said method comprising:
polishing the Ru film by bringing the wafer into sliding contact with a polishing pad;
measuring a thickness of the Ru film by a film thickness sensor while polishing the Ru film;
calculating a derivative value of an output value of the film thickness sensor;
detecting a predetermined point of change in the derivative value; and
determining a removal point of the Ru film from a point of time when the predetermined point of change is detected.

2. The method according to claim 1, wherein the predetermined point of change is a local maximum point or a local minimum point of the derivative value.

3. The method according to claim 1, wherein the removal point of the Ru film is a point of time when a predetermined period of time has elapsed from the point of time when the predetermined point of change is detected.

4. The method according to claim 3, wherein said predetermined period of time includes zero.

5. The method according to claim 1, wherein the polishing pad has a fine porous structure uniformly formed in the polishing pad in its entirety and has open cells formed in said fine porous structure.

6. The method according to claim 1, further comprising:
after determining the removal point of the Ru film, increasing polishing pressure applied from the wafer to the polishing pad; and
polishing the Ta film or TaN film by bringing the wafer into sliding contact with the polishing pad at the increased polishing pressure.

7. The method according to claim 1, further comprising:
after determining the removal point of the Ru film, lowering polishing pressure applied from the wafer to the polishing pad; and
polishing the Ta film or TaN film by bringing the wafer into sliding contact with the polishing pad at the lowered polishing pressure.

8. The method according to claim 1, wherein:
said polishing of the Ru film comprises polishing the Ru film by bringing the wafer into sliding contact with the polishing pad while supplying the polishing pad with a first polishing liquid; and
said method further comprises, after determining the removal point of the Ru film, polishing the Ta film or TaN film by bringing the wafer into sliding contact with the polishing pad while supplying the polishing pad with a second polishing liquid, instead of the first polishing liquid.

9. The method according to claim 1, further comprising:
before polishing the Ru film, polishing a copper film formed on the Ru film.

10. The method according to claim 9, wherein the Ru film and the Ta film or TaN film form a barrier layer for preventing copper diffusion.

11. The method according to claim 1, wherein the film thickness sensor is an eddy current sensor.
